(19) United States
(12) Patent Application Publication
(10) Pub. No.: US 2009/0108436 A1
(43) Pub. Date: Apr. 30, 2009

(54) SEMICONDUCTOR PACKAGE

(76) Inventors: Toshio Fujii, Osaka (JP); Masashi Funakoshi, Osaka (JP); Satoru Atsuta, Kyoto (JP)

Correspondence Address: MCDERMOTT WILL & EMERY LLP, 600 13TH STREET, NW, WASHINGTON, DC, 20005-3096, US

(21) Appl. No.: 12/099,986

(22) Filed: Apr. 9, 2008

(30) Foreign Application Priority Data
Oct. 31, 2007 (JP) 2007-283816
Jan. 28, 2008 (JP) 2008-016097

(51) Int. Cl. H01L 23/485

(52) U.S. Cl. 257/693; 257/E23.019

(57) ABSTRACT

In a semiconductor package, a semiconductor chip is adhered with an adhesive member, with a circuit face of the semiconductor chip facing upward, onto a circuit board including a plurality of interconnections, a plurality of through holes, wire bonding pads and a solder resist for protecting the interconnections and the through holes. A plurality of electrodes of the semiconductor chip are electrically connected to the plural wire bonding pads of the circuit board through wires. A concave is formed in the solder resist of the circuit board correspondingly to every through hole of the circuit board, and concaves present in a region opposing a rim portion of the semiconductor chip and a region surrounding the semiconductor chip are buried with a resin so as to attain a flat top face.

### CROSS-REFERENCE TO RELATED APPLICATIONS

This application claims priority under 35 U.S.C. §119 on Patent Applications No. 2007-283816 filed in Japan on Oct. 31, 2007, and No. 2008-016097 filed in Japan on Jan. 28, 2008, the entire contents of which are hereby incorporated by reference.

### BACKGROUND OF THE INVENTION

The present invention relates to a semiconductor package, and more particularly, it relates to a semiconductor package of a face up bonding structure.

An example of generally known semiconductor packages is a BGA (ball grid array) semiconductor package. A BGA semiconductor package has a package structure in which a semiconductor chip is provided on a side of a principal plane of a circuit board and a plurality of solder bumps working as external connection terminals are provided on a plane of the other side of the principal plane of the circuit board, and thus, the number of pins is increased and the package density is increased.

Various structures of the BGA semiconductor package have been developed and commercialized, and the structures are roughly divided into a face up bonding structure and a face down bonding structure.

In the face up bonding structure, a semiconductor chip is put on a circuit board with a circuit face of the semiconductor chip facing upward, and electrode pads formed on the circuit face of the semiconductor chip are electrically connected to electrode pads formed on the circuit board through wire bonding. Alternatively, in the face down bonding structure, a semiconductor chip is put on a circuit board with a circuit face of the semiconductor chip facing the circuit board, and electrode pads formed on the circuit face of the semiconductor chip are electrically connected to electrode pads formed on the circuit board through flip chip bonding.

On the other hand, in accordance with recent further reduction in the size, the thickness and the weight of electronic equipment such as portable information equipment, there are increasing demands for further increase of the density and improvement of the performance of semiconductor packages included in such electronic equipment.

In increasing the density of a semiconductor package, density increase of interconnections of a circuit board cannot be avoided, but in some cases, due to the restriction in reducing the size and the thickness of the semiconductor package, the interconnection density cannot be increased through the increase of the size of the circuit board or the increase of the thickness by increasing the number of layers.

FIG. 11A shows the cross-sectional structure of a conventional semiconductor package and FIG. 11B shows the wiring structure between a semiconductor chip and a circuit board in the conventional semiconductor package.

As shown in FIGS. 11A and 11B, the semiconductor package is designed so that a plurality of interconnections and through holes can be efficiently disposed for providing the maximum numbers of them in a limited region.

In such a conventional semiconductor package, however, a void is caused in fixing the semiconductor chip on the circuit board, so as to disadvantageously lower the reliability as a product. One factor of the occurrence of a void will now be described with reference to FIGS. 12A through 12D.

Each of FIGS. 12A through 12D shows the cross-sectional structure and the plane structure of the semiconductor package taken on line XII-XII of FIG. 11B. Specifically, FIG. 12A shows the structure obtained immediately after fixing a semiconductor chip 7 on a circuit board 6 with an adhesive member 8, FIGS. 12B and 12C show warp caused in the circuit board, and FIG. 12D shows a void caused after curing the adhesive member.

As shown in FIG. 12A, the semiconductor chip 7 is fixed with the adhesive member 8 onto the circuit board 6 including a substrate 1, interconnections 2 (see FIG. 11A) formed on upper and lower faces of the substrate 1, through holes 3 extending from the upper face to the lower face of the substrate 1 and a solder resist 5 formed so as to cover the interconnections 2 and the through holes 3. The top face of the solder resist 5 is not flat owing to the interconnections 2 and the through holes 3. Furthermore, the adhesive member is applied so as to bury a concave of the solder resist 5 formed above the through hole 3.

Next, as shown in FIG. 12B, the circuit board 6 is easily warped, and when the circuit board 6 is warped, the circuit board 6 is away from the semiconductor chip 7, and the adhesive member 8 is drawn toward the center of a fixing face between the circuit board 6 and the semiconductor chip 7, so as to form a gap.

Furthermore, as shown in FIG. 12C, when the circuit board 6 is warped in the opposite direction to the warp shown in FIG. 12B, the adhesive member 8 is pushed to be spread along a portion of the solder resist 5 lifted by the interconnection 2 formed on the upper face of the circuit board 6, and hence, the gap is taken into the inside of the adhesive member 8.

Thereafter, as shown in FIG. 12D, the gap taken into the inside of the adhesive member 8 is increased through a heat treatment performed for curing the adhesive member 8, and as a result, a void is caused.

Since the circuit board 6 is easily deformed in this manner, when the circuit board 6 is largely warped or repeatedly warped before curing the adhesive member 8, a void is easily caused, which is a factor to degrade the reliability of the semiconductor package. In particular, such a void tends to be caused in the vicinity of the center of a side of the semiconductor chip.

With respect to such a void caused between a semiconductor chip and a circuit board, for example, Japanese Laid-Open Patent Publication No. 2007-12716 (hereinafter referred to as Patent Document 1) discloses an invention for preventing the occurrence of a void through optimization of the amount of adhesive used for adhering a chip by setting the shortest distance between a wire bonding region and a die bonding region to 100 μm through 400 μm and further forming a groove between the wire bonding region and the die bonding region.

Alternatively, Japanese Laid-Open Patent Publication No. 2006-19651 (hereinafter referred to as Patent Document 2) discloses an invention for avoiding a void caused between a semiconductor chip and a circuit board in a semiconductor package of the face down bonding structure by apparently flattening, by polishing, a face of the circuit board on which the semiconductor chip is to be adhered while forming a linear polishing trace extending along one direction and including a plurality of fine grooves.

The inventions disclosed in Patent Documents 1 and 2 for preventing the occurrence of a void have the following problems:

The invention disclosed in Patent Document 1 aims to improve the reliability of connection between an electrode and a wire on the basis of an area occupied by the adhesive used for fixing the semiconductor chip on the circuit board, and does not recognize at all that a concave is formed in a resist formed on a circuit board by a through hole and an interconnection formed in and on the circuit board and that the thus formed concave causes a void between the semiconductor chip and the circuit board. Therefore, a void caused unavoidably when a concave is formed in the region on the circuit board opposing a rim portion of the semiconductor chip cannot be prevented by the invention of Patent Document 1. Also, in the case where a through hole is formed below the semiconductor chip for electric connection with an external substrate, an interconnection should be formed in a region on the circuit board opposing a peripheral portion of the semiconductor chip. However, a semiconductor device described in Patent Document 1 does not have an external terminal in a region on a face of the circuit board opposite to the face where the semiconductor chip is adhered, and therefore, this semiconductor device cannot be applied to the increase of the number of pins.

Also, in the structure described in Patent Document 2, the polishing trace is linearly formed along one direction on the face of the circuit board on which the semiconductor chip is adhered. Therefore, in spreading a paste of the adhesive member applied on the circuit board with the semiconductor chip to be connected to the circuit board, the paste is difficult to spread uniformly toward the four sides of the semiconductor chip, and it is disadvantageously difficult to control formation of a fillet such as a rise portion onto a circuit face of the semiconductor chip.

### SUMMARY OF THE INVENTION

In consideration of the aforementioned conventional disadvantages, an object of the invention is providing a highly reliable semiconductor package of the face up bonding structure in good yield by suppressing the occurrence of a void in the vicinity of the center of a side of a semiconductor chip.

In order to achieve the object, in the semiconductor package of this invention, a region on a circuit board opposing a rim portion of a semiconductor chip and a region on the circuit board surrounding the semiconductor chip are flattened.

Specifically, the semiconductor package of this invention includes a circuit board in which a plurality of interconnections, a plurality of through holes and a solder resist for protecting the plurality of interconnections and the plurality of through holes are formed; and a semiconductor chip fixed on a top face of the circuit board with an adhesive member and electrically connected to the circuit board, and a region on the circuit board opposing a rim portion of the semiconductor chip and a region on the circuit board surrounding the semiconductor chip have a flat top face.

In the semiconductor package of this invention, since the region on the circuit board opposing the rim portion of the semiconductor chip and the region on the circuit board surrounding the semiconductor chip have a flat top face, even when a warp state of the circuit board is changed before curing the adhesive member in a die bonding process, a bubble minimally enters the adhesive member. Therefore, even when the circuit board is thin and compact and has a high density, a highly reliable semiconductor package of the face up bonding structure can be realized in good yield.

In the semiconductor package, a resin is preferably provided on the region on the circuit board opposing the rim portion of the semiconductor chip and the region on the circuit board surrounding the semiconductor chip.

Thus, since the resin is provided in the region on the circuit board opposing the rim portion of the semiconductor chip and the region on the circuit board surrounding the semiconductor chip, the top face of the circuit board is flattened. Therefore, even when the warp state of the circuit board is changed before curing the adhesive member in the die bonding process, a distance between the semiconductor chip and the circuit board is not increased in any portion, and hence, a gap is minimally caused in the adhesive member after adhering the semiconductor chip onto the circuit board. Accordingly, occurrence of a void can be suppressed in the semiconductor package.

In the semiconductor package, the solder resist preferably includes a plurality of layers.

Thus, not only the region opposing the rim portion of the semiconductor chip and the region surrounding a semiconductor chip but also the whole top face of the circuit board is flattened. Therefore, the wet spread property of the adhesive member is improved so as to further suppress the occurrence of a void in the semiconductor package.

In the semiconductor package, the plurality of through holes are preferably formed in a region on the circuit board excluding a region opposing an end of the semiconductor chip.

Thus, no through hole is formed in the region on the circuit board opposing the end of the semiconductor chip, and hence, no level difference is caused on the top face of the circuit board in the region opposing the end of the semiconductor chip. Accordingly, even when the warp state of the circuit board is changed before curing the adhesive member in the die bonding process, a bubble minimally enters the adhesive member, so that the occurrence of a void can be suppressed in the semiconductor package.

In the semiconductor package in which the through holes are formed in the region on the circuit board excluding the region opposing the end of the semiconductor chip, the plurality of interconnections and the plurality of through holes preferably form via lands on the top face of the circuit board, and every through hole is preferably formed in a region on the circuit board away from the end of the semiconductor chip opposing the circuit board by a distance obtained by adding a thickness of each interconnection to a half of a difference between a diameter of the through hole and a diameter of a corresponding one of the via lands.

Thus, since no through hole is formed in the region on the circuit board opposing the end of the semiconductor chip, no level difference is caused on the top face of the circuit board in the region opposing the end of the semiconductor chip, and hence, the top face can be definitely flattened. Therefore, the occurrence of a void can be prevented.

In the semiconductor package in which the through holes are formed in the region on the circuit board excluding the region opposing the end of the semiconductor chip, every through hole preferably is formed in a region on the circuit board away in an inward direction from the end of the semiconductor chip opposing the circuit board by a distance of 100 μm or more.

Thus, since no through hole is formed in the region on the circuit board opposing the end of the semiconductor chip, no level difference is caused on the top face of the circuit board in the region opposing the end of the semiconductor chip, and hence, the top face can be definitely flattened. Therefore, the occurrence of a void can be prevented. Furthermore, even when an adhesion shift is caused, the occurrence of a void can be suppressed.

In the semiconductor package in which the through holes are formed in the region on the circuit board excluding the region opposing the end of the semiconductor chip, every through hole is preferably formed in a region on the circuit board away in an outward direction from the end of the semiconductor chip opposing the circuit board by a distance of 100 μm or more.

Thus, the occurrence of a void in the adhesive member used for adhering the semiconductor chip on the circuit board can be prevented.

In the semiconductor package in which the through holes are formed in the region on the circuit board excluding the region opposing the end of the semiconductor chip, every through hole is preferably formed in a region on the circuit board away in an outward direction from the end of the semiconductor chip opposing the circuit board by a distance of 100 μm.

Thus, since no through hole is formed in the region on the circuit board opposing the end of the semiconductor chip, the top face of the circuit board can be definitely flattened. Therefore, the occurrence of a void can be prevented.

In the semiconductor package, a wettability ratio of the adhesive member used for fixing the semiconductor chip on the circuit board is preferably 80% or more.

Thus, the occurrence of a void and peeling can be more definitely prevented.

In the semiconductor chip in which the wettability ratio of the adhesive member is 80% or more, the semiconductor chip is preferably fixed on the circuit board in the region on the circuit board opposing the rim portion of the semiconductor chip excluding a center of a side of the semiconductor chip.

Thus, even when the adhesive member is not provided at the center of a side of the semiconductor chip in the region on the circuit board opposing the rim portion of the semiconductor chip, the occurrence of a void and peeling can be prevented as far as the wettability ratio of the adhesive member is 80% or more.

In the semiconductor chip, adjacent interconnections out of the plurality of interconnections are preferably not formed in parallel to each other in a region on the circuit board opposing an end of the semiconductor chip.

Thus, a bubble minimally enters the adhesive member used for adhering the semiconductor chip onto the circuit board in the die bonding process, the occurrence of a void between the circuit board and the semiconductor chip is suppressed in the semiconductor package.

### BRIEF DESCRIPTION OF THE DRAWINGS

FIG. 1 is a cross-sectional view of a semiconductor package according to Embodiment 1 of the invention.

FIGS. 2A, 2B, 2C, 2D, 2E and 2F are cross-sectional views for showing fabrication procedures for the semiconductor package of Embodiment 1 of the invention.

FIG. 3 is a cross-sectional view of a semiconductor package according to Embodiment 2 of the invention.

FIGS. 4A, 4B, 4C, 4D, 4E, 4F and 4G are cross-sectional views of fabrication procedures for a circuit board of the semiconductor package of Embodiment 2 of the invention.

FIGS. 5A, 5B, 5C, 5D and 5E are cross-sectional views of fabrication procedures for the semiconductor package of Embodiment 2 of the invention.

FIG. 6 is a cross-sectional view of a semiconductor package according to Embodiment 3 of the invention.

FIG. 7 is another cross-sectional view of the semiconductor package of Embodiment 3 of the invention.

FIGS. 8A and 8B are enlarged cross-sectional views of the semiconductor package of Embodiment 3, and specifically, FIG. 8A shows a part of FIG. 6 and FIG. 8B shows a part of FIG. 7.

FIG. 9 is a plan view of an adhesive member used in a semiconductor package according to Embodiment 4 of the invention.

FIG. 10 is a plan view for showing the wiring structure of a semiconductor package according to Embodiment 5 of the invention.

FIGS. 11A and 11B are diagrams of a conventional semiconductor package, and specifically, FIG. 11A is a cross-sectional view thereof and FIG. 11B is a plan view for showing the wiring structure between a semiconductor chip and a circuit board.

FIGS. 12A, 12B, 12C and 12D are cross-sectional views and plan views taken on line XII-XII of FIG. 11B for showing a factor of occurrence of a void in the conventional semiconductor package.

### DETAILED DESCRIPTION OF THE INVENTION

### Embodiment 1

Embodiment 1 of the invention will now be described with reference to the accompanying drawings.

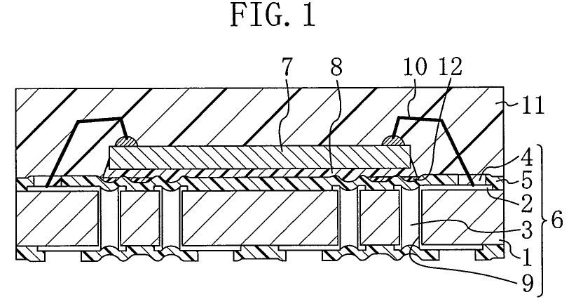

FIG. 1 shows the cross-sectional structure of a semiconductor package according to Embodiment 1 of the invention.

As shown in FIG. 1, in the semiconductor package of Embodiment 1, a semiconductor chip 7 is fixed, with a circuit face thereof facing upward, with an adhesive member 8 onto a circuit board 6 including a substrate 1, a plurality of interconnections 2 provided on an upper face and a lower face of the substrate 1, through holes 3 extending from the upper face to the lower face of the substrate 1, wire bonding pads 4 provided on the upper face of the substrate 1, and a solder resist 5 for protecting the interconnections 2 and the through holes 3. A metal film is formed on the inner wall of each through hole 3 so as to form a via 9, and the interconnection 2 provided on the upper face of the substrate 1 is electrically connected to the interconnection 2 provided on the lower face through the via 9. A plurality of electrodes of the semiconductor chip 7 are electrically connected to a plurality of wire bonding pads 4 formed on the circuit board 6 through wires 10. Also, a top face of the circuit board 6, namely, the face on which the semiconductor chip 7 is adhered, is encapsulated with an encapsulation resin 11. The surface of the solder resist 5 is not flat because convexes are formed correspondingly to the interconnections and concaves are formed correspondingly to the through holes 3. A resin 12 is provided in a region on the solder resist opposing a rim portion of the semiconductor chip 7 and a region on the solder resist surrounding the semiconductor chip 7, so as to flatten the top face of the solder resist 5.

In this manner, a level difference caused on the top face of the circuit board 6 in the region opposing the rim portion of the semiconductor chip 7 and in the region surrounding the semiconductor chip 7 is 4 μm or less, and thus the top face can be flattened.

The material for the substrate 1 of Embodiment 1 is not particularly specified and examples of the material are a reinforcing material of glass, aramid or the like impregnated with a bismaleimide-triazine resin (a BT resin), an epoxy resin, a polyester resin, a polyimide resin or a phenol resin, and ceramics.

Furthermore, the via 9 is obtained by forming the through hole 3 by using a laser beam or a drill in the fabrication of the circuit board 6 and forming a metal film on the inner wall of the through hole 3 by nonelectrolytic plating or electrolytic plating.

Also, in the circuit board 6, part of the interconnections 2 is exposed for forming the wire bonding pads 4 in the peripheral portion on the face where the semiconductor chip 7 is fixed, and the plural wire bonding pads 4 made of, for example, a Ni layer or an Au layer are formed on the exposed part of the interconnections 2. The face of the circuit board 6 on which the semiconductor chip 7 is fixed is covered with the solder resist 5 excluding the wire bonding pads 4.

Moreover, the materials for the adhesive member 8 and the encapsulation resin 11 are not particularly specified, and for example, a resin composition of an epoxy resin or an acrylic resin may be used.

Also, the material for the resin 12 is not particularly specified, and for example, a resin composition of an epoxy resin or an acrylic resin may be used.

According to the semiconductor package of Embodiment 1 of the invention, since the resin 12 is provided in the region on the circuit board 6 opposing the rim portion of the semiconductor chip 7 and the region on the circuit board 6 surrounding the semiconductor chip 7, the region on the circuit board 6 opposing the rim portion of the semiconductor chip 7 and the region on the circuit board 6 surrounding the semiconductor chip 7 have a flat top face. Therefore, even when the warp state of the circuit board 6 is changed before curing the adhesive member 8 in a die bonding process, a distance between the semiconductor chip 7 and the circuit board 6 is never increased in any portion, and hence, a gap is minimally formed in the adhesive member 8 after adhering the semiconductor chip 7 onto the circuit board 6. Thus, the occurrence of a void can be suppressed. Accordingly, even when a circuit board with a small thickness and a high density is used, a highly reliable semiconductor package of the face up bonding structure can be realized in good yield by providing the resin 12 for flattening the top face of the circuit board.

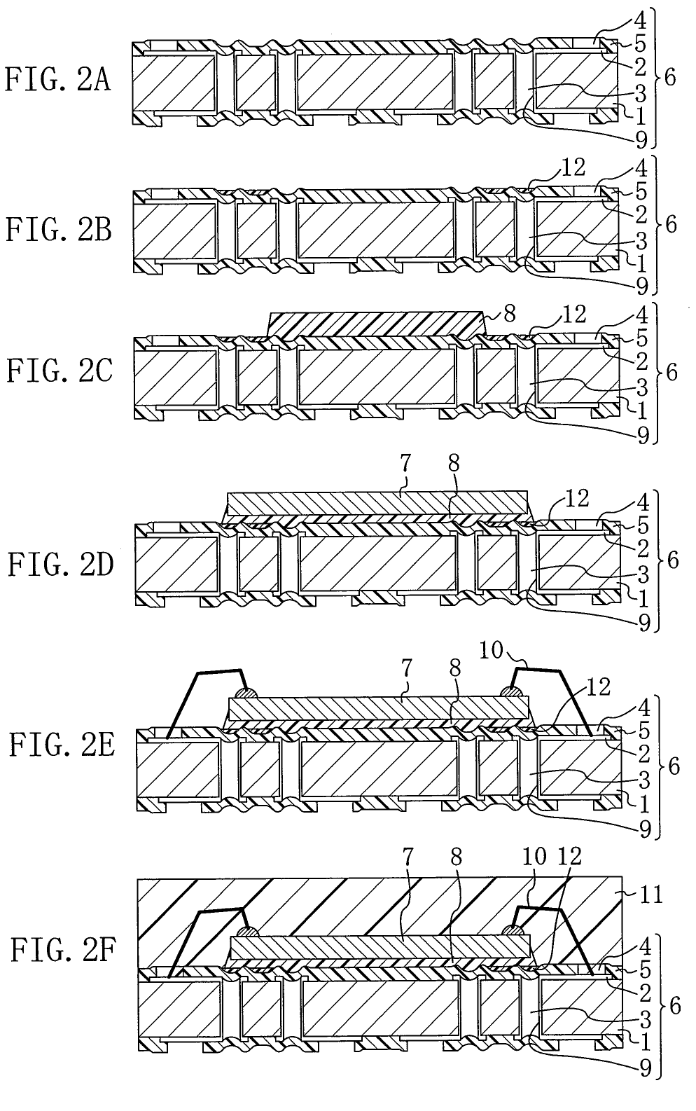

FIGS. 2A through 2F are cross-sectional views for schematically showing fabrication procedures of the semiconductor package of Embodiment 1. In FIGS. 2A through 2F, like reference numerals are used to refer to like elements shown in FIG. 1.

First, as shown in FIG. 2A, a circuit board 6 including interconnections 2 formed on the upper and lower faces of a substrate 1 and on inner walls of through holes 3; a plurality of through holes 3 extending from the upper face to the lower face of the substrate 1; wire bonding pads 4 formed in a peripheral portion on the upper face of the substrate 1; and a solder resist 5 formed so as to cover the interconnections 2 formed on the upper and lower faces of the substrate 1 and the through holes 3 is prepared.

Next, as shown in FIG. 2B, among concaves formed in providing the solder resist 5 on the top face of the circuit board 6, concaves disposed in a region surrounding a semiconductor chip 7 are flattened by providing a resin 12. The method for providing the resin 12 is not particularly specified, and for example, a resin composition of an epoxy resin or an acrylic resin is put in the corresponding positions by a potting method or a printing method and is pressed for flattening with a flat plate or the like having a face parallel to the top face of the circuit board after a heat treatment. Alternatively, the resin 12 may be provided through exposure and development by photolithography.

Then, as shown in FIG. 2C, an adhesive member 8 of an epoxy resin or the like is applied on a center portion of the solder resist 5 formed on the top face of the circuit board 6. The amount of adhesive member 8 in an uncured state to be applied on the circuit board 6 is adjusted so that the adhesive member 8 can attain a thickness of approximately 30 μm through 50 μm after curing. The method for applying the adhesive member 8 is not particularly specified, and for example, the potting method or the printing method may be employed.

Next, as shown in FIG. 2D, the semiconductor chip 7 having been ground into a desired thickness in a back grinding process and having been cut into a desired size in a dicing process is pressed, with a circuit face thereof facing upward, against the adhesive member 8 provided on the top face of the circuit board 6, so as to be adhered while spreading the adhesive member 8. At this point, the load to be applied is adjusted so that the adhesive member 8 cannot be allowed to rise up to the top face of the semiconductor chip 7 but that the adhesive member 8 can form a fillet for covering a part of the side face of the semiconductor chip 7. Thereafter, the adhesive member 8 is cured.

Then, as shown in FIG. 2E, electrodes provided on the circuit face corresponding to the top face of the semiconductor chip 7 are wire bonded to the wire bonding pads 4 provided on the circuit board 6 by using wires 10.

Ultimately, as shown in FIG. 2F, an encapsulation resin 11 of an epoxy resin or the like is provided for resin encapsulation so as to cover the whole top face of the circuit board 6 including the semiconductor chip 7 and the wires 10.

In subsequent procedures not shown in the drawing, solder balls for external connection used for mounting on a mother board or the like are formed and the resultant semiconductor package is cut into pieces if necessary, resulting in completing a semiconductor product.

Although the resin 12 is provided in the region on the circuit board 6 opposing the rim portion of the semiconductor chip 7 and the region on the circuit board surrounding the semiconductor chip 7 for flattening the top face of the circuit board 6 in Embodiment 1, the method for flattening the top face is not limited to the provision of the resin 12 as far as the top face can be flattened. Alternatively, the top face of the circuit board 6 may be flattened by providing the resin 12 over the whole region on the circuit board 6 opposing the semiconductor chip 7.

### Embodiment 2

Embodiment 2 of the invention will now be described with reference to the accompanying drawings.

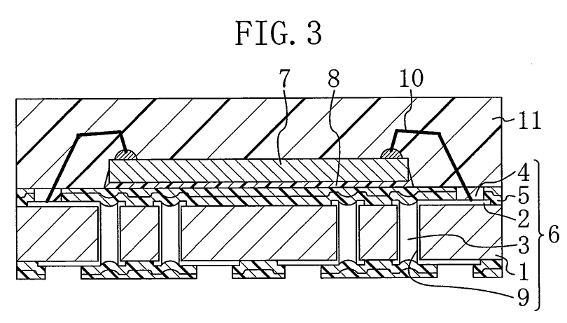

FIG. 3 shows the cross-sectional structure of a semiconductor package according to Embodiment 2 of the invention. In FIG. 3, like reference numerals are used to refer to like elements shown in FIG. 1 so as to omit the description. As a characteristic of Embodiment 2, a solder resist 5 formed on a substrate 1 is composed of a plurality of layers.

As shown in FIG. 3, a level difference caused in the solder resist 5 formed on the upper and lower faces of the substrate 1 by a convex derived from an interconnection 2 and a concave derived from a through hole 3 is smaller in the semiconductor package of this embodiment than a level different caused in a general single-layered solder resist, and hence, the top face of the solder resist 5 composed of a plurality of layers is flatter. In other words, as the number of layers included in the solder resist 5 is larger, the level difference is smaller and the top face of the solder resist 5 is flatter.

According to the semiconductor package of Embodiment 2 of the invention, not only a level difference caused in a region surrounding a semiconductor chip 7 among level differences caused in the solder resist 5 formed on the circuit board 6 having the interconnections 2 and the through holes 3 but also the whole top face of the circuit board 6 including a region where the semiconductor chip 7 is adhered is flattened. Therefore, the wet spread property and the like of an adhesive member 8 is improved so as to further suppress the occurrence of a void. As a result, a highly reliable semiconductor package of the face up bonding structure can be realized in good yield.

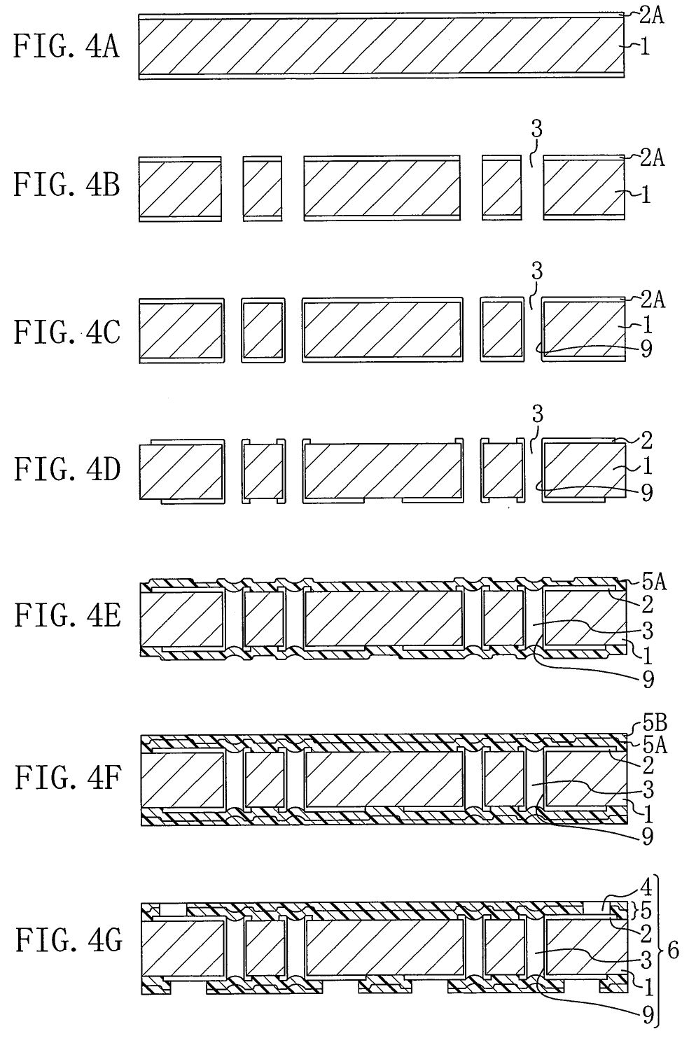

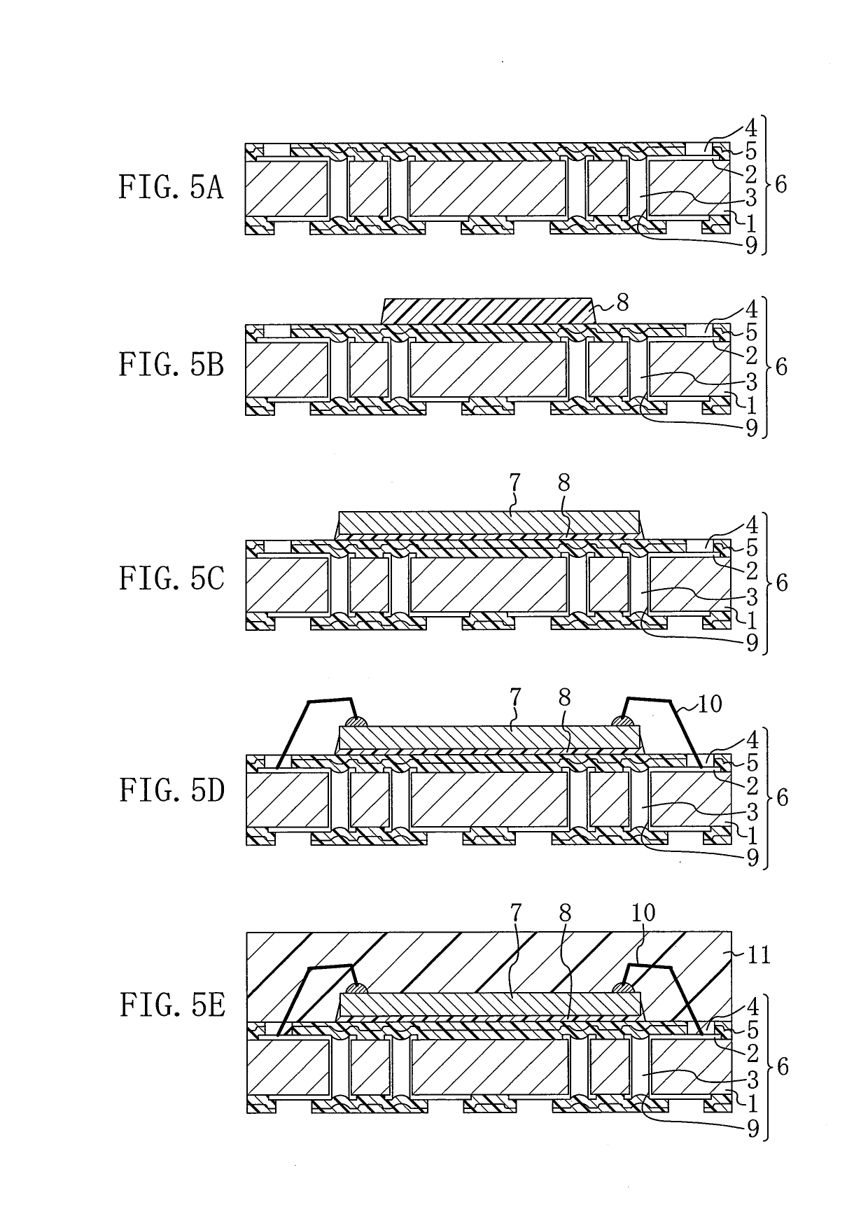

FIGS. 4A through 4G are cross-sectional views for schematically showing fabrication procedures for the circuit board used in the semiconductor package of Embodiment 2 of the invention, and FIGS. 5A through 5E are cross-sectional views for schematically showing fabrication procedures for the semiconductor package of Embodiment 2. Also in FIGS. 4A through 4G and 5A through 5E, like reference numerals are used to refer to like elements shown in FIG. 1 so as to omit the description.

First, as shown in FIG. 4A, a circuit board 6 is made of a copper-clad laminate in which a copper foil 2A is formed on an upper face and a lower face of a substrate 1 made of, for example, glass woven fabric impregnated with an epoxy resin.

Next, as shown in FIG. 4B, through holes 3 extending from the upper face to the lower face of the substrate 1 including the copper foil 2A are formed by using a laser beam or a drill.

Then, as shown in FIG. 4C, the inner walls of the through holes 3 are plated by a panel plating method so as to form vias 9.

Subsequently, as shown in FIG. 4D, the copper foil 2A formed on the upper and lower faces of the substrate 1 is etched into a desired conductive pattern of a circuit so as to form interconnections 2.

At this point, a multilayered substrate including four or more layers may be formed as the copper-clad laminate used in FIG. 4A. In this case, a two-layered substrate including a substrate and a copper foil is used as a primary multilayered substrate, and a secondary multilayered substrate (not shown) is obtained in a similar manner to that described above by adhering a copper foil above an upper face and a lower face of the primary multilayered substrate with an insulating resin such as prepreg sandwiched therebetween. A multilayered substrate (not shown) including a desired number of layers may be obtained by repeating these procedures, and ultimately, holes extending from the upper face to the lower face of the resultant multilayered substrate are formed for interlayer connection between, for example, an outermost layer and an inner layer. Thus, a multilayered substrate with desired interlayer connection can be obtained.

Next, as shown in FIG. 4E, a solder resist ink with photosensitivity to UV is applied on the upper and lower faces of the substrate 1, and the solder resin ink is tentatively cured by drying so as to form a first photosensitive layer 5A. At this point, the solder resist ink applied on the substrate 1 has a convex correspondingly to the interconnection 2 and a concave correspondingly to the through hole 3, and hence, the top face of the solder resist ink is not flat.

Then, as shown in FIG. 4F, a solder resist ink with photosensitivity to UV is further applied on the first photosensitive layer 5A formed in the procedure of FIG. 4E and is tentatively cured by drying so as to form a second photosensitive layer 5B. Although not shown in the drawing, photosensitive layers are similarly repeatedly formed so as to be laminated. A level difference caused in a general one-layered solder resist by the interconnection 2 and the through hole 3 is reduced in the size by staking a plurality of layers in this manner. Thus, a level difference caused in a solder resist 5 correspondingly to the interconnection 2 and the through hole 3 formed on and in the circuit board 6 is reduced in the size while stacking a plurality of layers of the solder resist 5. Thus, the top face of the circuit board 6 including a region where a semiconductor chip 7 is to be adhered is flattened.

Next, as shown in FIG. 4G, a necessary portion is selectively exposed for photopolymerization in an exposure process performed by UV irradiation through an exposure film of a negative pattern on which a desired pattern is drawn. Thereafter, an unexposed portion is dissolved in a development process using a sodium carbonate aqueous solution or the like, and an exposed portion is not dissolved but remains on the upper face and the lower face of the substrate 1. Then, the solder resist ink is thermally cured by a heat treatment, so as to form the solder resist 5 composed of the plural layers.

Next, processes for fabricating the semiconductor package of Embodiment 2 by adhering a semiconductor chip 7 onto the thus formed circuit board 6 will be described.

First, as shown in FIG. 5A, the circuit board 6 on which the solder resist 5 composed of the plural layers is formed is prepared by the method described with reference to FIGS. 4A through 4G.

Next, as shown in FIG. 5B, an adhesive member 3 of an epoxy resin or the like is applied on a center portion of the solder resist 5 disposed on the top face of the circuit board 6. At this point, the amount of adhesive member 8 in an uncured state to be applied on the circuit board 6 is adjusted so that the adhesive member 8 can attain a thickness of approximately 30 μm through 50 μm after curing. The method for applying the adhesive member 8 is not particularly specified, and for example, the potting method or the printing method may be employed as described in Embodiment 1.

Next, as shown in FIG. 5C, the semiconductor chip 7 having been ground into a desired thickness in the back grinding process and having been cut into a desired size in the dicing process is pressed, with a circuit face thereof facing upward, against the adhesive member 8 provided on the top face of the circuit board 6, so as to be adhered while spreading the adhesive member 8. At this point, the load to be applied is adjusted so that the adhesive member 8 cannot be allowed to rise up to the top face of the semiconductor chip 7 but that the adhesive member 8 can form a fillet for covering a part of the side face of the semiconductor chip 7. Thereafter, the adhesive member 8 is cured.

Then, as shown in FIG. 5D, electrodes provided on the circuit face corresponding to the top face of the semiconductor chip 7 are wire bonded to wire bonding pads 4 provided on the circuit board 6 by using wires 10.

Ultimately, as shown in FIG. 5E, an encapsulation resin 11 of an epoxy resin or the like is provided for resin encapsulation so as to cover the whole top face of the circuit board 6 including the semiconductor chip 7 and the wires 10.

In subsequent procedures not shown in the drawing, solder balls for external connection used for mounting on a mother board or the like are formed and the resultant semiconductor package is cut into pieces if necessary, resulting in completing a semiconductor product.

Although the solder resist 5 includes two layers in the drawings referred to in Embodiment 2, it goes without saying that the solder resist 5 preferably includes a plurality of layers so as to flatten the top face of the circuit board 6. Alternatively, the top face of the circuit board 6 may be flattened by forming a single-layered solder resist 5 in a large thickness.

### Embodiment 3

Embodiment 3 of the invention will now be described with reference to the accompanying drawing and a table.

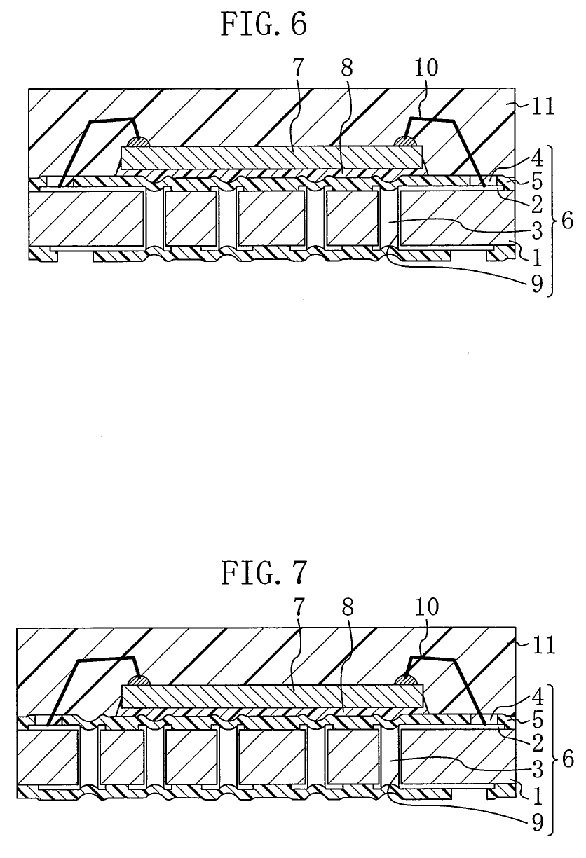

FIGS. 6 and 7 show the cross-sectional structure of a semiconductor package according to Embodiment 3 of the invention. In FIGS. 6 and 7, like reference numerals are used to refer to like elements shown in FIG. 1 so as to omit the description. As a characteristic of Embodiment 3, a through hole 3 is not formed in a region on a circuit board 6 opposing an end of a semiconductor chip 7 but is formed in a region on the circuit board 6 away from the end of the opposing semiconductor chip 7 by a given or larger distance.

As shown in FIG. 6, a through hole 3 is formed so as to penetrate a substrate 1 from its upper face to its lower face, a metal film is formed on the inner wall of the through hole 3 so as to form a via 9, and the metal film of the via 9 is connected to interconnections 2 formed on the upper and lower faces of the substrate 1. In a portion on the top face of the circuit board 6 including the through hole 3 and the interconnection 2 connected to the via 9, a via land 13 (not shown) is formed. Therefore, the top face of a solder resist 5 covering the through hole 3 and the via land 13 is not flat. In the solder resist 5, a concave is formed correspondingly to the through hole 3 and a convex is formed correspondingly to the interconnection 2. Since no through hole 3 is formed in a region on the circuit board 6 opposing the end of the semiconductor chip 7, the circuit board 6 has a flat top face in the region opposing the end of the semiconductor chip 7.

Furthermore, as shown in FIG. 7, a through hole 3 is not formed in a region on the circuit board 6 corresponding to the end of the opposing semiconductor chip 7 but is formed in a region on the circuit board 6 corresponding to the outside of the semiconductor chip 7. Therefore, the circuit board 6 has a flat top face in the region opposing the end of the semiconductor chip 7.

In this manner, no level difference is caused in the region on the circuit board 6 opposing the end of the semiconductor chip 7. Therefore, a void caused in the adhesive member 8, which is formed when the circuit board 6 is warped before curing an adhesive member 8 in the die bonding process and a distance between the circuit board 6 and the semiconductor chip 7 is increased due to a level difference so as to form a gap between the adhesive member 8 and the circuit board 6 or the semiconductor chip 7, or which is formed because the gap is taken into the adhesive member 8 when the warp is restored, can be suppressed. Accordingly, a highly reliable semiconductor package of the face up bonding structure can be realized in good yield.

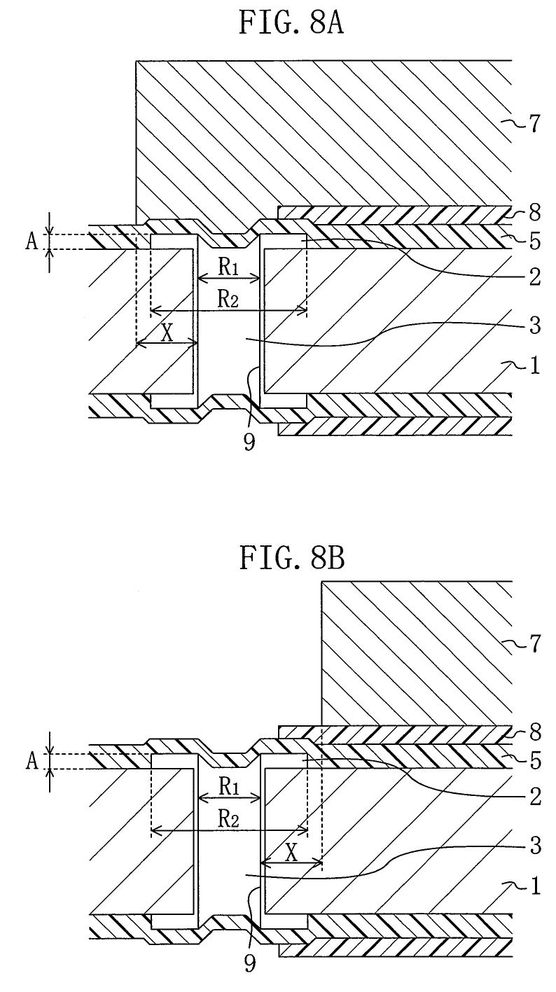

FIGS. 8A and 8B are diagrams for showing the positional relationship between the semiconductor chip 7 and the through hole 3 in the circuit board 6, and specifically, FIG. 8A shows the through hole 3 formed correspondingly to the inside of the opposing semiconductor chip 7 and FIG. 8B shows the through hole 3 formed correspondingly to the outside of the opposing semiconductor chip 7.

As shown in FIGS. 8A and 8B, when a distance X between the through hole 3 and the end of the semiconductor chip 7 is larger than a length obtained by adding a thickness A of the interconnection 2 to a half of a difference between the diameter R, of the through hole 3 and the diameter R₂ of the via land 13, the region on the circuit board 6 opposing the end of the semiconductor chip 7 has a flat top face.

For example, when a through hole 3 is formed to be away from the end of the semiconductor chip 7 by 100 μm or more, the occurrence of a void can be suppressed even if an adhesion shift or the like is caused between the semiconductor chip 7 and the circuit board 6.

In this manner, when a through hole 3 or a via land 13 is formed to be away from the end of the opposing semiconductor chip 7 by 100 μm or more, a void derived from an adhesion shift or the like can be further suppressed. Therefore, even when a circuit board with a small thickness and a high density is used, a highly reliable semiconductor package of the face up bonding structure can be realized in good yield. Furthermore, since a region where the through hole 3 is formed is a portion of the circuit board 6 opposing the semiconductor chip 7, the semiconductor package is effectively refined.

At this point, the relationship between the thickness of the circuit board 6 and the distance on the circuit board 6 from the end of the opposing semiconductor chip 7 to the through hole 3 formed correspondingly to the outside of the semiconductor chip 7 will be described.

TABLE 1

| | | Distance from end of semiconductor | | | |
|---|---|---|---|---|---|
| | | chip to through hole formed outside | | | |
| | | 0 μm | 50 μm | 100 μm | 200 μm |
| Thickness of | 500 μm | OK | OK | OK | OK |
| substrate | 300 μm | NG | NG | OK | OK |
| | 200 μm | NG | NG | OK | OK |
| | 100 μm | NG | NG | OK | OK |

Table 1 shows whether or not a void is caused under various conditions of the thickness of a circuit board and the distance on the circuit board from the end of an opposing semiconductor chip to a through hole formed correspondingly to the outside of the semiconductor chip.

Circuit boards used in an experiment for obtaining the result shown in Table 1 are glass epoxy substrates with a size of 10 mm×10 mm and a thickness of 100 μm, 200 μm, 300 μm and 500 μm. A semiconductor chip used in the experiment is a mirror wafer having a size of 6 mm×6 mm and a thickness of 200 μm after the back grinding process and the wafer dicing process. An adhesive member used for adhering the semiconductor chip onto the circuit board is a dice bonding paste with viscosity of a given value ranging between 5 Pa·s and 30 Pa·s. Semiconductor packages are fabricated by using them to be used in the experiment. The adhesive member is applied on a single point in a fixing face of the circuit board where the semiconductor chip is to be adhered by using an air pulse type dispenser. Then, the semiconductor chip is pressed against the top face of the circuit board with a load of 100 g so as to spread the adhesive member and adhere the semiconductor chip onto the circuit board, and the adhesive member is cured by allowing the resultant to stand for 1 hour at a temperature of 170° C. In semiconductor packages in which the thickness of the circuit board and the distance on the circuit board from the end of the opposing semiconductor chip to the through hole formed correspondingly to the outside of the semiconductor chip are varied, the occurrence of voids is examined through nondestructive evaluation of observation by a supersonic imaging device (SAT) and destructive evaluation of cross-sectional analysis. In Table 1, “OK” means that no void is found in the semiconductor package and “NG” means that a void is found in the semiconductor package.

As shown in Table 1, in the semiconductor package including the circuit board with a comparatively large thickness of 500 μm, no void is caused no matter where a thorough hole is formed. Also, in the semiconductor packages including the circuit boards with a thickness of 100 μm through 300 μm, no void is caused as far as the distance on the circuit board from the end of the opposing semiconductor chip to the through hole formed correspondingly to the outside of the semiconductor chip is 100 μm or more.

In other words, since a circuit board included in a BGA semiconductor package has a thickness of 100 μm through 300 μm owing to the height restriction, when a through hole 3 is formed on the circuit board 6 in a position away from the end of the opposing semiconductor chip 7 by a distance of 100 μm or more, the occurrence of a void can be suppressed. Furthermore, in consideration of an adhesion shift, when a via 9 is formed on the circuit board 6 in a position away from the end of the opposing semiconductor chip 7 by a distance of 100 μm or more, the occurrence of a void can be more definitely suppressed. Moreover, when a via land 13 is formed on the circuit board 6 in an outside region away from the end of the semiconductor chip 7 by 100 μm or more, the occurrence of a void can be further suppressed.

In this manner, when a through hole 3 is formed to be away from the end of a semiconductor chip opposing a circuit board in the outward direction by 100 μm or more, a highly reliable semiconductor package of the face up bonding structure can be realized in good yield.

Moreover, the occurrence of a void in the adhesive member 8 can be suppressed by forming a through hole 3 in an inside or outside region on the circuit board 6 away from the end of the opposing semiconductor chip 7 by 100 μm or more. Accordingly, in order to increase the number of pins and the density, through holes 3 are formed in both the inside and outside regions on the circuit board 6 away from the end of the opposing semiconductor chip 7 by 100 μm or more.

### Embodiment 4

Embodiment 4 of the invention will now be described with reference to the accompanying drawing and a table. As a characteristic of Embodiment 4, an area where an adhesive member is provided and the thickness of the adhesive member are specified as given ranges.

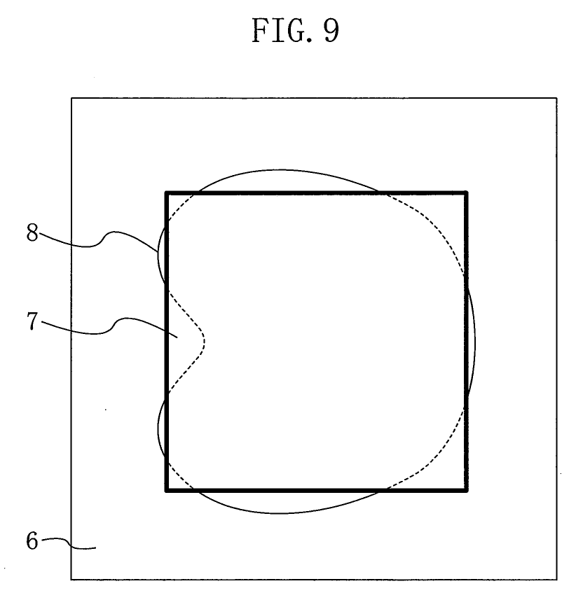

FIG. 9 shows an example of an area occupied in a semiconductor chip by an adhesive member used for adhering the semiconductor chip onto a circuit board (i.e., a wettability ratio). Also, Table 2 below shows whether or not a void or peeling is caused in a semiconductor package under various relationships between the wettability ratio and the thickness of the adhesive member.

TABLE 2

| | | Thickness of adhesive member | | | | | |
|---|---|---|---|---|---|---|---|
| | | 3 μm | 5 μm | 10 μm | 20 μm | 50 μm | 100 μm |
| Wetta- | 100% | NG | OK | OK | OK | OK | OK |
| bility | 90% | NG | OK | OK | OK | OK | OK |
| ratio | 80% | NG | OK | OK | OK | OK | OK |
| | 70% | NG | NG | NG | NG | NG | NG |
| | 50% | NG | NG | NG | NG | NG | NG |

Each semiconductor package used for obtaining the results shown in Table 2 is fabricated under the following conditions: A semiconductor chip made of a mirror wafer having a size of 6 mm×6 mm and a thickness of 200 μm after the back grinding process and the wafer dicing process is fixed onto a circuit board made of a glass epoxy resin with a size of 10 mm×10 mm and a thickness of 200 μm with a dice bonding paste having viscosity of a given value of 5 Pa·s through 30 Pa·s. Since a through hole formed in the circuit board is formed in a position away from the end of the opposing semiconductor chip by a distance of 200 μm, a region on the circuit board opposing the end of the semiconductor chip has a flat top face.

The adhesive member is applied on a single point in a fixing face of the circuit board where the semiconductor chip is to be adhered by using an air pulse type dispenser. Then, the semiconductor chip is pressed against the top face of the circuit board so as to spread the adhesive member and adhere the semiconductor chip onto the circuit board. At this point, the adhesive member is applied so that the thickness of the adhesive member attained after curing can be 3 μm, 5 μm, 10 μm, 20 μm or 50 μm and the wettability ratio of the adhesive member can be 50%, 70%, 80%, 90% or 100%.

Each semiconductor package fabricated in the aforementioned manner is subjected to evaluation for a void or peeling. It is examined through the nondestructive evaluation of the observation by a supersonic imaging device (SAT) and the destructive evaluation of the cross-sectional analysis whether or not a void has been caused.

Furthermore, each semiconductor package having been encapsulated with a resin is subjected to a reliability evaluation test. Specifically, after allowing the semiconductor package to stand at 125° C. for 4 hours, a solder resistance reflow test is performed, and it is determined whether or not peeling due to steam explosion (popcorn crack) has been caused. The solder resistance reflow test is performed as follows: After the semiconductor package is allowed to absorb moisture by allowing it to stand at 30° C. and relative humidity of 60%, that is, level 3 of MSL (moisture sensitive level) according to JEDEC (Joint Electron Device Engineering Council), for 192 hours, the resultant semiconductor package is allowed to stand at 260° C. (265° C. at peak) for 10 seconds. Thereafter, it is determined through observation by the nondestructive evaluation of a supersonic imaging device (SAT) and the destructive evaluation of the cross-sectional analysis whether or not the peeling has been caused. In Table 2, “OK” means that neither a void nor peeling is found in the semiconductor package and “NG” means that at least one of a void and peeling is found in the semiconductor package.

As shown in Table 2, in the semiconductor packages where a void or peeling is found, when the thickness of the adhesive member is 3 μm, a void is caused regardless of the wettability ratio of the adhesive member, and when the wettability ratio of the adhesive member is 70% or less, peeling is caused. Furthermore, when the thickness of the adhesive member is 100 μm and the wettability ratio is 80% or more, neither a void nor peeling is found, but when the thickness of the adhesive member is 100 μm, it is apprehended that a problem of inclination of the semiconductor chip or the like may occur because the moisture absorption to the adhesive member or the thickness of the adhesive member is not constant. Moreover, also due to the restriction in the height of the semiconductor package, the upper limit of the thickness of the adhesive member is approximately 50 μm. Accordingly, when the thickness of the adhesive member is not less than 5 μm and not more than 50 μm and the wettability ratio is 80% or more, neither a void nor peeling is caused in the adhesive member.

According to the semiconductor package of Embodiment 4 of the invention, a region on the top face of a circuit board opposing the end of a semiconductor chip is flat, and in the procedure for adhering the semiconductor chip onto the circuit board with an adhesive member, the thickness of the adhesive member attained after curing is not less than 5 μm and not more than 50 μm and the area occupied by the adhesive member in the area of the semiconductor chip is 80% or more. Thus, the occurrence of a void and peeling can be prevented.

Although the region on the top face of the circuit board opposing the end of the semiconductor chip is flattened without forming a through hole therein in Embodiment 4, a region opposing a rim portion of the semiconductor chip and a region surrounding the semiconductor chip may be flattened by, for example, providing a resin in a concave formed correspondingly to a through hole or by forming a solder resist composed of a plurality of layers.

Furthermore, the wettability ratio of the adhesive member of 80% or more may be an area occupied by the adhesive member in the area of the semiconductor chip as shown in FIG. 9. Specifically, the adhesive member may be provided in a region corresponding to 80% or more of the area of the semiconductor chip excluding a center portion of a side corresponding to the rim portion of the semiconductor chip. Thus, a void and peeling can be prevented.

### Embodiment 5

Embodiment 5 of the invention will now be described with reference to the accompanying drawing.

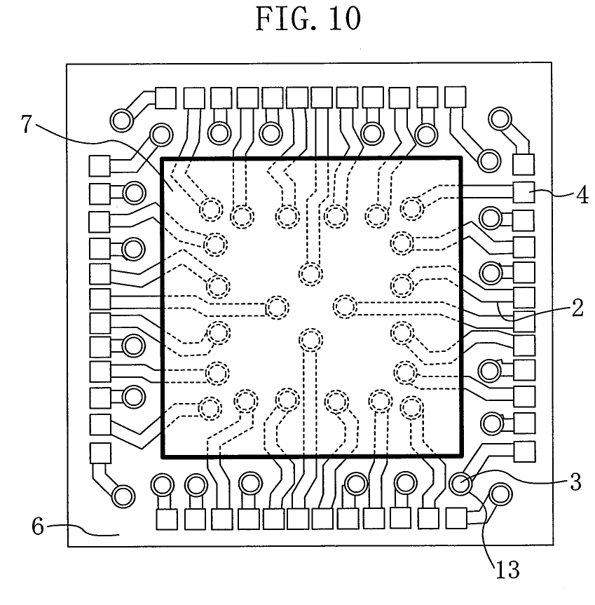

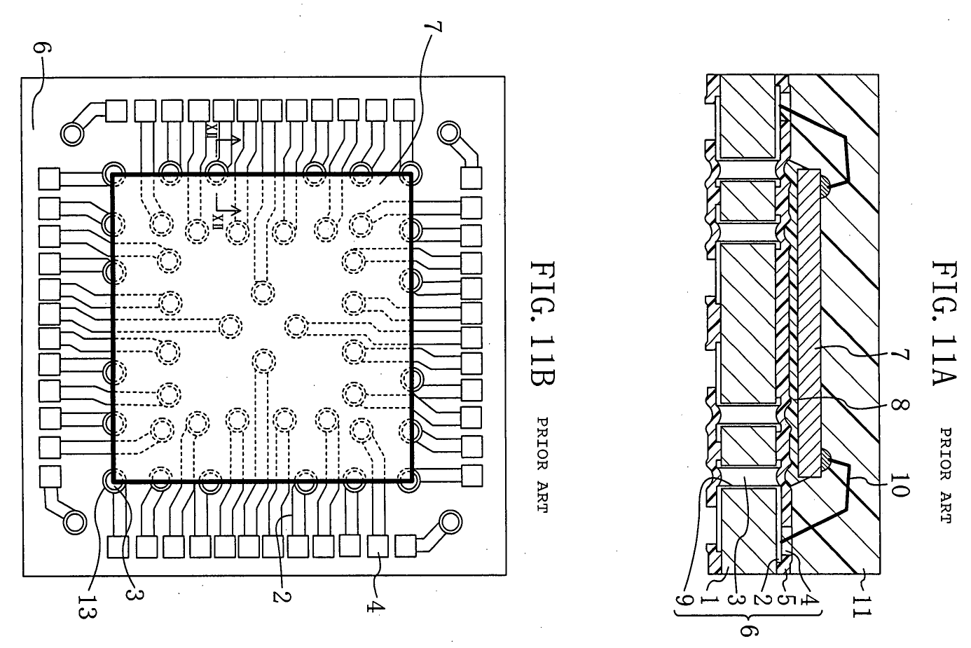

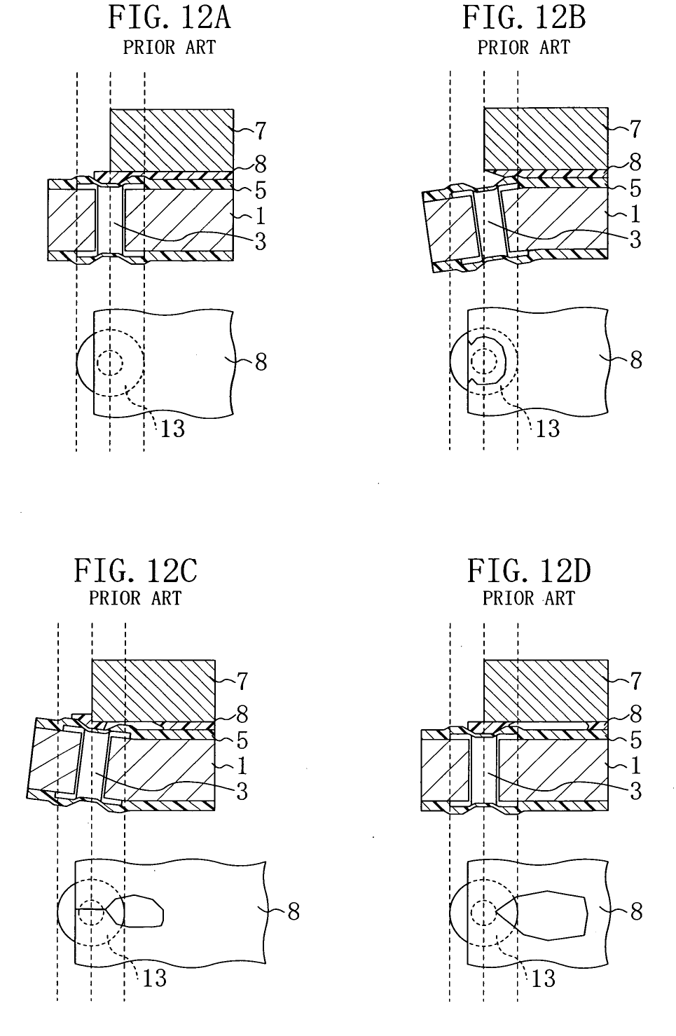

FIG. 10 shows a wiring structure between a semiconductor chip and a circuit board. In FIG. 10, like reference numerals are used to refer to like elements shown in FIG. 1 so as to omit the description. As a characteristic of Embodiment 5, interconnections 2 adjacent to each other are not parallel to each other in a region on a circuit board 6 opposing an end of a semiconductor chip 7.

As shown in FIG. 10, the interconnections 2 formed on the circuit board 6 connect wiring bonding pads 4 to through holes 3. In these interconnections, an interconnection 2 connected to a through hole 3 formed in a region on the circuit board 6 opposing the semiconductor chip 7 is formed so as to extend from the region on the circuit board 6 opposing the semiconductor chip 7 to a region not opposing the semiconductor chip 7. When interconnections 2 adjacent to each other are not parallel to each other in the region opposing the end of the semiconductor chip 7, a gap is minimally taken into an adhesive member 8 as compared with the case where the adjacent interconnections are parallel.

In this manner, the occurrence of a void between the circuit board 6 and the semiconductor chip 7 can be suppressed. In the case where interconnections 2 formed adjacently on the circuit board 6 are parallel to each other and oppose the end of the semiconductor chip 7, if the warp state of the circuit board 6 is changed before curing the adhesive member 8 in the die bonding process, a force to draw the adhesive member 8 along a concave formed between the interconnections formed on the circuit board 6 opposing the semiconductor chip 7 is caused. Therefore, a gap formed in a portion filled with the adhesive member 8 is taken into the adhesive member 8, so as to cause a void. However, when the structure of Embodiment 5 is employed, a gap minimally enters the adhesive member 8 as a bubble. Accordingly, the occurrence of a void between the circuit board 6 and the semiconductor chip 7 is suppressed, and hence, even when a circuit board with a small thickness and a high density is used, a highly reliable semiconductor package of the face up bonding structure can be realized in better yield.

Although the description is principally given on the semiconductor package including a two-layered substrate in each embodiment above, a single-layered or a multilayered substrate may be used instead, and the description of each embodiment does not limit the invention.

As described so far, according to the semiconductor package of this invention, a highly reliable semiconductor package of the face up bonding structure applicable to a thin substrate can be realized in good yield, and the invention is useful for further reducing the size, the weight and the thickness of electronic equipment.

1-3. (canceled)

4. A semiconductor package comprising:
a circuit board in which a plurality of interconnections, a plurality of through holes and a solder resist for protecting the plurality of interconnections and the plurality of through holes are formed; and
a semiconductor chip fixed on a top face of the circuit board with an adhesive member and electrically connected to the circuit board,
wherein all of the through holes are formed in a region on the circuit board excluding a region opposing an end of the semiconductor chip.

5. The semiconductor package of claim 4,
wherein the plurality of interconnections and the plurality of through holes form via lands on the top face of the circuit board, and
all of the through holes are formed in a region on the circuit board away from the end of the semiconductor chip opposing the circuit board by a distance obtained by adding a thickness of each interconnection to a half of a difference between a diameter of the through hole and a diameter of a corresponding one of the via lands.

6. The semiconductor package of claim 8, wherein all of the through holes are formed in a region on the circuit board away in an inward direction from the end of the semiconductor chip opposing the circuit board by a distance of 100 μm or more.

7. The semiconductor package of claim 8, wherein all of the through holes are formed in a region on the circuit board away outward direction from the end of the semiconductor chip opposing the circuit board by a distance of 100 μm or more.

8. The semiconductor package of claim 5, wherein all of the through holes are formed in a region on the circuit board away from the end of the semiconductor chip opposing the circuit board by a distance of 100 μm.

9. The semiconductor package of claim 5, wherein an end of each of all the via lands connected to an inner wall of a corresponding one of the plurality of through holes and formed on the top face of the circuit board is away, on the circuit board, from the end of the semiconductor chip opposing the circuit board by a distance of 100 μm or more.

10. The semiconductor chip of claim 4, wherein a wettability ratio of the adhesive member used for fixing the semiconductor chip on the circuit board is 80% or more.

11. The semiconductor chip of claim 10, wherein the semiconductor chip is fixed on the circuit board in the region on the circuit board opposing the rim portion of the semiconductor chip excluding a center of a side of the semiconductor chip.

12. The semiconductor chip of claim 4, wherein adjacent interconnections out of the plurality of interconnections are not formed in parallel to each other in a region on the circuit board opposing an end of the semiconductor chip.
